(19) United States
(12) Patent Application Publication
(10) Pub. No.: US 2020/0159880 A1
(43) Pub. Date: May 21, 2020

(54) INFORMATION PROCESSING DEVICE AND NON-TRANSITORY COMPUTER READABLE MEDIUM

(71) Applicant: FUJI XEROX CO., LTD., Tokyo (JP)

(72) Inventor: Yoichi WATANABE, Kanagawa (JP)

(73) Assignee: FUJI XEROX CO., LTD., Tokyo (JP)

(21) Appl. No.: 16/673,968

(22) Filed: Nov. 5, 2019

(30) Foreign Application Priority Data
Nov. 16, 2018 (JP) 2018-215518

(51) Int. Cl. G06F 17/50; B29C 64/112; B29C 64/393; B29C 64/135

(52) U.S. Cl. CPC G06F 17/5018; B29C 64/112; B33Y 50/02; B29C 64/135; B29C 64/393

(57) ABSTRACT

An information processing device includes a storage unit, a selection receiver, and a formable data construction unit. The storage unit stores, for each of a formative cell configured as a collection of multiple formative voxels that each are a minimum unit of formation by a forming device, specification information enabling a specification of which of multiple materials is used to form each formative voxel included in the formative cell, and physical properties of the formative cell. The selection receiver receives a selection of any formative cell stored in the storage unit as the material of each region included in an object. A formable data construction unit that replaces each region of the object with a collection of the formative cells received by the selection receiver for the region, and thereby constructs formable data expressing the object as a collection of the formative voxels each having a stipulated material.

### CROSS-REFERENCE TO RELATED APPLICATIONS

This application is based on and claims priority under 35 USC 119 from Japanese Patent Application No. 2018-215518 filed Nov. 16, 2018.

### BACKGROUND

### (i) Technical Field

The present disclosure relates to an information processing device and a non-transitory computer readable medium.

### (ii) Related Art

Devices that form three-dimensional objects, such as 3D printers, are becoming more widespread. Regarding the data formats used with 3D printers, formats that describe a 3D shape with a polygon mesh representation, like the Standard Triangulated Language (STL) format and the 3DS format for example, are being used widely.

Also, the applicants have proposed a data format called “FAV” that describes a 3D model to be formed by a 3D printer with a voxel representation (see Tomonari Takashi, Masahiko Fujii, “The Next-Generation 3D Printing Data Format FAV, Which Enables an Unprecedented Wide Range of Expression”, [online], Fuji Xerox Technical Report, No. 26, 2017, [retrieved Sep. 21, 2018], Internet <URL: https://www.fujixerox.co.jp/company/technical/tr/2017/pdf/s_07.pdf>). In the FAV format, voxels are given various attributes such as color, material, link strength with other voxels, and the like, thereby enabling the expression of various characteristics besides the 3D shape.

The method of generating a topology for a material disclosed in Japanese Unexamined Patent Application Publication No. 2013-65326 includes: a step of parameterizing one or multiple material characteristics of a material using a computer, in which the parameterizing step includes a step of parameterizing one or multiple strength-related material characteristics including yield strength, breaking strength, and hardness by limiting a repeating microstructure expressing the material, and a step of executing one or multiple virtual tests in which real application of at least one field to the material is simulated using different microstructures in each virtual test; and a step of simulating generating a topology for the material on the basis of the parameterization.

### SUMMARY

By assigning materials individually to each voxel, a higher degree of freedom in the design of the physical properties of an object over the case of using a single material is obtained. For example, by changing the combination of voxels of individual materials in each region of the object, it is possible to make the physical properties different in each region. This means that design according to a method that designates the physical properties instead of designating the material to use in the regions of the object becomes possible.

However, to design an object that is formable by a forming device, it is desirable to designate physical properties that are achievable with combinations of materials used by the forming device.

Aspects of non-limiting embodiments of the present disclosure relate to providing support enabling one to designate physical properties that are formable by a forming device as the physical properties of elements of an object.

Aspects of certain non-limiting embodiments of the present disclosure address the features discussed above and/or other features not described above. However, aspects of the non-limiting embodiments are not required to address the above features, and aspects of the non-limiting embodiments of the present disclosure may not address features described above.

According to an aspect of the present disclosure, there is provided an information processing device including: a storage unit that stores, for each of a formative cell configured as a collection of multiple formative voxels that each are a minimum unit of formation by a forming device, specification information enabling a specification of which of multiple materials is used to form each formative voxel included in the formative cell, and physical properties of the formative cell; a selection receiver that receives a selection of any formative cell stored in the storage unit as the material of each region included in an object; and a formable data construction unit that replaces each region of the object with a collection of the formative cells received by the selection receiver for the region, and thereby constructs formable data expressing the object as a collection of the formative voxels each having a stipulated material.

### BRIEF DESCRIPTION OF THE DRAWINGS

An exemplary embodiment of the present disclosure will be described in detail based on the following figures, wherein:

FIG. 1 is a diagram for explaining a unit cell (that is, a level 1 cell);

FIGS. 2A to 2D are diagrams for explaining analysis that accounts for the mixing of the materials of adjacent voxels in the same layer;

FIG. 3 is a diagram for explaining analysis that accounts for the distribution of the extent of cure in the depth direction inside a voxel;

FIG. 4 is a diagram for explaining a functional configuration of an object data processing device that performs resolution conversion;

FIGS. 5A and 5B are diagrams for explaining in-layer mix information stored in a basic data storage unit;

FIG. 6 is a diagram for explaining adhesion information stored in the basic data storage unit;

FIGS. 7A and 7B is a diagram for explaining curing information stored in the basic data storage unit;

FIG. 8 is a diagram illustrating an example of information about formative cells in each level registered in a cell information DB;

FIG. 9 is a diagram illustrating an example of a processing procedure by an object data processing device;

FIG. 10 is a diagram illustrating an example of a first part of a processing procedure by a cell replacement unit for resolution conversion;

FIG. 11 is a diagram illustrating an example of a remaining part of a processing procedure by the cell replacement unit for resolution conversion;

FIG. 12 is a diagram illustrating an example of a processing procedure by a resolution conversion unit;

FIG. 13 is a diagram illustrating a different example of the processing procedure by the cell replacement unit;

FIG. 14 is a diagram for explaining a functional configuration of the object data processing device that generates a structural analysis model from object data;

FIG. 15 is a diagram illustrating an example of a processing procedure by the cell replacement unit in an example of generating a structural analysis model from object data;

FIG. 16 is a diagram illustrating a different example of a processing procedure by the cell replacement unit in an example of generating a structural analysis model from object data;

FIG. 17 is a diagram for explaining a functional configuration of the object data processing device that has a function of deciding material in units of voxels to achieve desired physical properties; and

FIGS. 18A and 18B are diagrams illustrating an example of a UI screen provided in the device of FIG. 17.

### DETAILED DESCRIPTION

<Unit Cell>

In a 3D printer that forms objects by an inkjet method, an object is formed by jetting material (for example, resin) in a molten state onto a target site forming a shape and radiating curing energy, such as ultraviolet rays for example, to cure the material. Formation is performed in units of layers, and every time the formation of one layer is completed, the formation of the next layer is performed. By jetting materials with different physical properties (mechanical properties such as strength and Young's modulus, for example) from multiple nozzles, it is possible to form an object with multiple materials. By using a model that represents a thing to be formed in units of voxels and designating for each voxel the material forming that voxel (for example, by assigning an identifier of the material to a material attribute of the voxel), the forming device becomes able to form an object by jetting material individually for each voxel in accordance with the model. In the following, the thing to be formed will be called the object, and the model representing the object as a collection of voxels will be called the object data. In the object data, by designating a material for each voxel, it becomes possible to give individual parts of the object separately desired mechanical properties.

At this point, it takes some time for the material jetted and adhesed to a target site (in other words, a voxel position) to cure. During this time, the material at the site mixes somewhat with the material adhesed to neighboring sites in the same layer. This does not pose a problem if the adjacent materials are the same, but if the materials are different from each other, the physical properties of the mixed part become different from the original physical properties of each of the materials.

Also, since the format of each individual layer takes some time, at the point in time when a material is jetted onto a target site from a nozzle, the material of the voxel in the layer below that material has cured enough such that mixing does not occur. However, how much the cured material and the material jetted on top adhere to each other varies depending on the combination of the top and bottom materials.

In addition, the material jetted and adhesed to a target site is irradiated with curing energy such as ultraviolet rays, thereby promoting the curing of the material. At this point, the curing energy emitted from a radiation source is radiated from above the layer of material, but attenuates as the energy proceeds deeper from the surface of the material, and the curing action also attenuates accordingly. For this reason, the extent of cure is different depending on the depth, even inside a single formed voxel.

For example, in the case of performing a structural analysis of an object on the basis of object data in which a material is designated for each voxel, given the various circumstances described above, if one assumes that the individual voxels are formed uniformly from each corresponding material, an appropriate analysis result may not be obtained. In contrast, if a structural analysis model is constructed to account for the mixing of materials between adjacent voxels, the degree of adhesion between layer, and the extent of cure according to the depth inside a layer described above for the individual voxels of the object model, an accurate analysis may be performed. However, since the structural analysis model becomes complex, the analysis ends up taking a long time.

Also, in the case in which the object data and the forming device have different resolutions, or in other words, the voxels of the object data and the voxels of the forming device have different sizes, the object expressed by the object data may not be formed completely correctly by the forming device in some cases. Particularly, in the case in which the resolution of the object data is finer than the resolution of the forming device, the parts where the materials of individual voxels are different in the object data will not be reproduced correctly by the forming device in principle. Note that in the forming device, a “voxel” refers to the smallest unit solid in the formation by the forming device.

However, if a cluster containing multiple voxels close to each other is treated as a unit, it is possible to reproduce, with a forming device, voxels or voxel clusters having physical properties (for example, mechanical properties) that are substantially the same as the physical properties of that cluster in the object data. In other words, the physical properties of a cluster are largely determined from the material of each voxel included in the cluster, the mixing between these voxels, the adhesion between layers, and the depth-direction distribution of the extent of cure in a layer. In the case of computing the physical properties of a voxel cluster in object data and reproducing the voxel cluster with the voxels of a forming device, if the materials of the individual voxels are decided such that the physical properties are substantially the same as the physical properties of the voxel cluster, an object reproducing the physical properties of the object data in units of voxel clusters is formed.

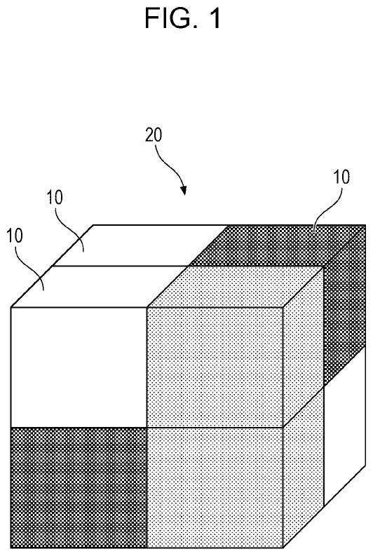

For several reasons like the above, the exemplary embodiment introduces a “unit cell” containing multiple voxels close to each other. A unit cell is a cube or a rectangular cuboid containing multiple voxels adjacent to each other. For example, consider the unit cell 20 illustrated in FIG. 1, which contains 2×2×2 (that is, 2 vertically, 2 horizontally, and 2 in the depth direction) for a total of 8 voxels 10 adjacent to each other. In this example, the unit cell 20 is a cube that is 2 voxels on a side. In the diagram, differences in the material of each voxel are represented as differences in the illustrated color of each voxel.

Additionally, a larger unit cell may also be used, such as a unit cell containing 3×3×3=27 voxels adjacent to each other, or a unit cell containing 4×4×4=64 voxels. However, as the voxels included in the unit cell become more numerous, the combinations of materials of the voxels forming the unit cell become more numerous, which causes the calculation time for computing the physical properties for each combination to become much longer.

In the exemplary embodiment, for example, by treating a unit cell as the unit of structural analysis and replacing unit cells of the object data with unit cells of the forming device with substantially the same physical properties, the above issues are addressed.

<Physical Properties of Unit Cell>

In the technique of the present exemplary embodiment, to utilize a unit cell, the physical properties of the unit cell are found by experiment, calculated by simulation, or a combination of the two. The physical properties of a unit cell are computed from the combination of the following three elements.

(1) Mixing of Material Between Adjacent Voxels in the Same Layer

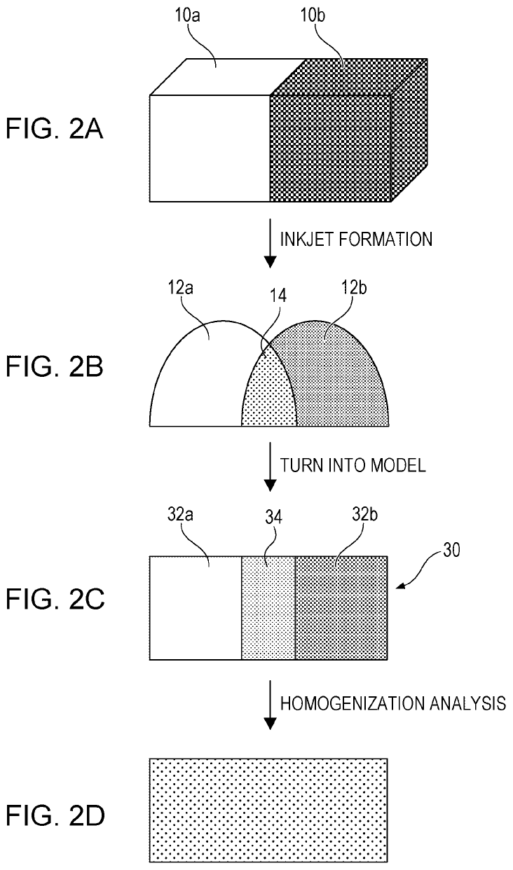

Consider the two voxels 10a and 10b adjacent to each other in the same layer illustrated by example in FIG. 2A. Assume that the materials of the two voxels 10a and 10b are different. Also, assume that the individual materials forming these two voxels 10 are jetted onto their respective voxel positions from inkjet nozzles or nozzle groups at the same time, or during the short time until the material that is jetted first cures enough to no longer mix with the material that is jetted second.

In this case, as illustrated in FIG. 2B, the fluid materials 12a and 12b adhering to the respective positions of the adjacent voxels 10a and 10b start to mix from the mutually contacting part, and form a mixed region 14. In this mixed region 14, the materials 12a and 12b mix together, and strictly speaking, the degree of mixing is different depending on location.

To compute the physical properties of two adjacent voxels that include such mixing, as illustrated in FIG. 2C, a structural analysis model 30 in which a mixed region 34 is set in the center is configured with respect to the two adjacent voxels 10a and 10b. In the illustrated example, the structural analysis model 30 includes three regions, namely, a region 32a of only the material 12a, a region 32b of only the material 12b, and the mixed region 34 between the two, in which the two materials are mixed together. The width (the width in the arrangement direction of the two adjacent voxels 10a and 10b) and the physical properties (such as the strength, Young's modulus, and Poisson's ratio) of the mixed region 34 are computed by experiment or numerical simulation.

For example, in the case of experiment, the mixed region is specified by adjacently jetting different materials at the same time for example at the resolution of a forming device (for example, a 3D printer) that forms a three-dimensional object, and observing the microstructure of the formed result with an electron microscope or the like. Also, the strength and other physical properties of the mixed region may be measured. In the case of numerical simulation, the mixed region is specified by constructing an analytical model of when different materials are formed adjacently at a voxel size corresponding to the resolution of the forming device, and by analyzing the analytical model using multiphase flow analysis techniques such as the volume of fluid (VOF) method and the moving particle semi-implicit (MPS) method. Subsequently, from information about the mixed region specified in this way, the width of the mixed region 14 in the case of creating a model like in FIG. 2C is decided.

In the illustrated example, the model is provided with a single mixed region 34 between the original region 32a of only the material 12a and the original region 32b of only the material 12b, but multiple mixed regions having different mix ratios may also be provided in the arrangement direction of the voxels 10a and 10b.

For example, the two voxels 10 and 10b may be considered to form a single cell, and if the structural analysis model 30 is used to perform homogenization analysis (also called the homogenization method), physical properties may be calculated for when the cell is treated as containing a single material. In homogenization analysis, by periodically disposing a structural analysis model while setting boundary conditions, and performing a numerical simulation on the periodically disposed structural analysis models, the physical properties for the case in which the structure indicated by the models is formed from a single material (hereinafter also called the “equivalent material physical properties”) are computed.

In the case in which the materials of the adjacent voxels 10a and 10b are the same, the physical properties do not change even if the materials mix with each other. Consequently, it is sufficient to generate the physical properties of the structural analysis model 30 that accounts for the mixing of materials or the homogenization analysis result of the model for each combination of two different materials.

FIGS. 2A to 2D illustrate the case of two adjacent voxels, but a structural analysis model and equivalent material physical properties may also be computed according to similar techniques for adjacent voxel groups arranged in other configurations, such as three contiguous voxels in a single direction, four voxels in a 2×2 arrangement in a single layer of the unit cell 20 illustrated in FIG. 1, or the like.

(2) Adhesion of Adjacent Voxels Between Layers

Adhesion information about voxels adjacent to each other between two adjacent layers is found by experiment or numerical simulation.

By experiment, for example, a sample is formed for each combination of two materials by jetting and curing droplets of material in a first layer, and then jetting and curing droplets of material in a second layer on top of the first layer. Subsequently, by running mechanical test on the samples, adhesiveness evaluation indexes such as one or both of the peel strength and the shear strength between layers are measured.

By numerical simulation, the adhesive state between a cured material in a first layer and a cured material in a second layer deposited on top of the first layer is analyzed by a technique such as molecular dynamics or nanosimulation, and adhesiveness evaluation indexes are computed from the analysis result.

In the analysis of the mixing of materials between adjacent voxels in the same layer described above, only combination of different materials are investigated, but for the indexes of the adhesive state of adjacent voxels between layers, voxels of the same material are also investigated.

(3) Differences in the Extent of Cure According to Depth

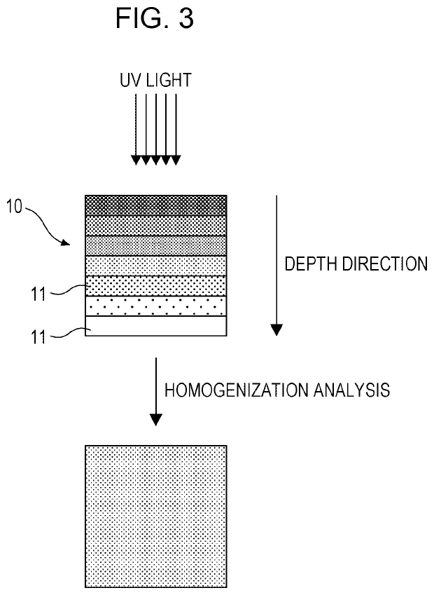

As described above, the extent of cure of a material is different depending on the depth from the surface hit by curing energy such as ultraviolet rays (that is, the distance in the direction of travel of the curing energy). Accordingly, by experiment or numerical simulation for each material, as illustrated in FIG. 3, the extent of cure for each depth range in the lamination direction of formation from the surface nearer the curing energy source of the voxel 10, or in other words, an extent-of-cure distribution in the depth direction, is computed.

For example, by experiment, the relationship between the amount of curing energy and the extent of cure (also called the reaction rate) is measured for each material by infrared spectrum measurement using Fourier-transform infrared spectroscopy (FT-IR) or the like. Since the amount of curing energy (for example, the intensity of ultraviolet rays) at each depth from the surface inside a voxel may computed according to the Beer-Lambert law, the extent of cure at each depth may be computed from the measurement result and the amount of energy at each depth.

The physical properties of a unit cell are calculated using a structural analysis model indicating a state of bonding between the multiple voxels forming the unit cell. The three elements described above are reflected in the structural analysis model.

For example, consider the case of a unit cell containing 2×2×2 voxels illustrated by example in FIG. 1. Given a method in which in-layer formation by the forming device advances by 1 voxel width at a time, for two adjacent voxels along the advancement direction of the formation, the structural analysis model (FIG. 2C) accounting for the mixing of materials between two adjacent voxels in the above (1) applies. In the case in which the two adjacent voxels in the formation advancement direction are the same material, a structural analysis model containing the same material for the two voxels applies. A total of four pairs of structural analysis models are produced. Furthermore, the region of each voxel in the pairs of structural analysis models are subdivided into depth ranges from the surface of the voxel. Additionally, with respect to the region of each depth range in the individual voxels, an extent of cure corresponding to the combination of the material of the voxel and the depth range is set ((3) described above). Furthermore, with respect to the structural analysis models subdivided in this way, for each pair of voxels adjacent to each other between layers and each pair of voxels adjacent to each other between rows in the same layer, adhesion information (namely, peel strength, shear strength, and the like) corresponding to the combination of the materials of the adjacent voxels is set as a boundary condition ((2) described above). Of the voxels adjacent between rows, the voxels formed earlier have cured to some degree at the point in time when a later voxel is formed, the mixing of materials between these voxels may be treated as not occurring, and two voxels adjacent between layers may be handled similarly. With this arrangement, a structural analysis model of a unit cell is constructed. Strictly speaking, the depth distribution of the extent of cure and the information about the adhesion between adjacent voxels is influenced by the mixing of different materials between adjacent voxels, but the original values for the materials before mixing may be utilized as practical approximate values which are good enough not to pose a problem.

By performing homogenization analysis on the structural analysis model of the unit cell constructed in this way, the equivalent material physical properties of the unit cell are calculated.

Note that as described above, the size of the unit cell is not limited to 2×2×2 and may also be a larger size such as 3×3×3 or 5×5×5 for example, but if the size is increased in this way, the structural analysis model of the unit cell becomes complex, which increases the amount of calculation (for example, the calculation time) taken by structural analysis.

<Higher-Order Cell>

If voxel groups are replaced with the 2×2×2 unit cells illustrated by example above, the number of component elements in the object is reduced by approximately 1/8. However, this still may be too many component elements in some cases.

On the other hand, if the size of the unit cell is increased to 5×5×5 or 8×8×8 or the like for example, the number of component elements in the object may be reduced, but as described above, increasing the size of the unit cell increases the amount of calculation taken to calculate the physical properties of the unit cell.

Accordingly, a “higher-order cell” is introduced. A higher-order cell is a cell containing multiple adjacent unit cells. For example, let a cell containing 2×2×2 adjacent unit cells be designated a level 1 (in other words, a first-order) cell. The unit cells are level 0 (in other words, zeroth-order) cells so to speak. By a similar rule, higher-level cells may be introduced recursively, such as a level 2 cell containing 2×2×2 adjacent level 1 cells, and a level 3 cell containing 2×2×2 adjacent level 2 cells.

The physical properties of a level 1 cell are computed by using a structural analysis model constructed from the unit cell group included therein. For each unit cell in the model, the equivalent material physical properties of each unit cell are set. Subsequently, by performing homogenization analysis on the structural analysis model, the equivalent material physical properties of the level 1 cell are computed. Similarly, the physical properties of a level k cell (where k is an integer equal to or greater than 1) are calculated by performing homogenization analysis using a structural analysis model constructed from the level (k−1) cell group included therein.

Note that an upper limit on the cell levels to apply to object data is set within a range in which the cells are treated as a microstructure with respect to the size of the object expressed by the object data, or in other words, within a range in which sufficiently numerous cells (that is, a number equal to or greater than a predetermined threshold value) may be disposed repeatedly in a region corresponding to the object.

<Resolution Conversion>

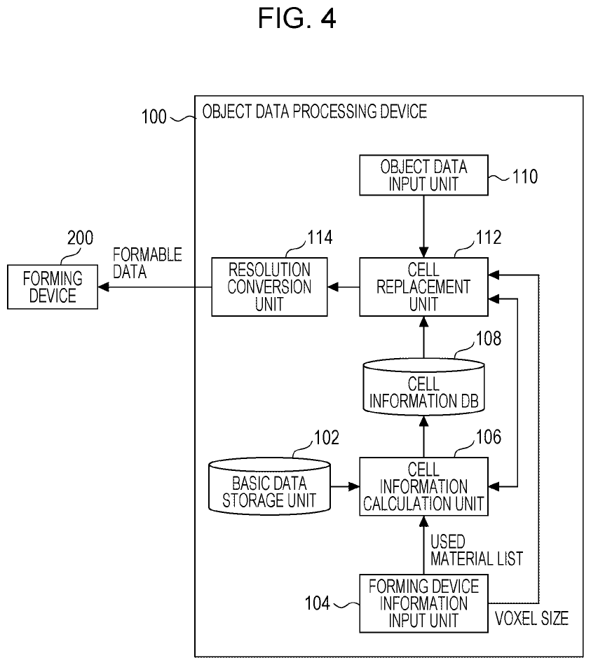

FIG. 4 illustrates one example of the configuration of an object data processing device 100 utilizing unit cells. This example is a device that converts object data into data (called formable data) in the resolution of a forming device 200. In the following, data representing an object in the resolution of the forming device 200 is called formable data. Formable data represents an object whose units are the voxels of the forming device. The forming device 200 is a three-dimensional inkjet forming device that forms objects using multiple materials. The forming device 200 is provided with for example separate nozzles for each material using in formation, and forms objects by jetting the corresponding material from each of these nozzles. Note that the forming device 200 is a device that acts as the target of resolution conversion in the object data processing device 100, but does not necessarily have to be connected to the object data processing device 100 as illustrated in the diagram. The object data processing device 100 may also perform the resolution conversion by targeting a virtual forming device 200.

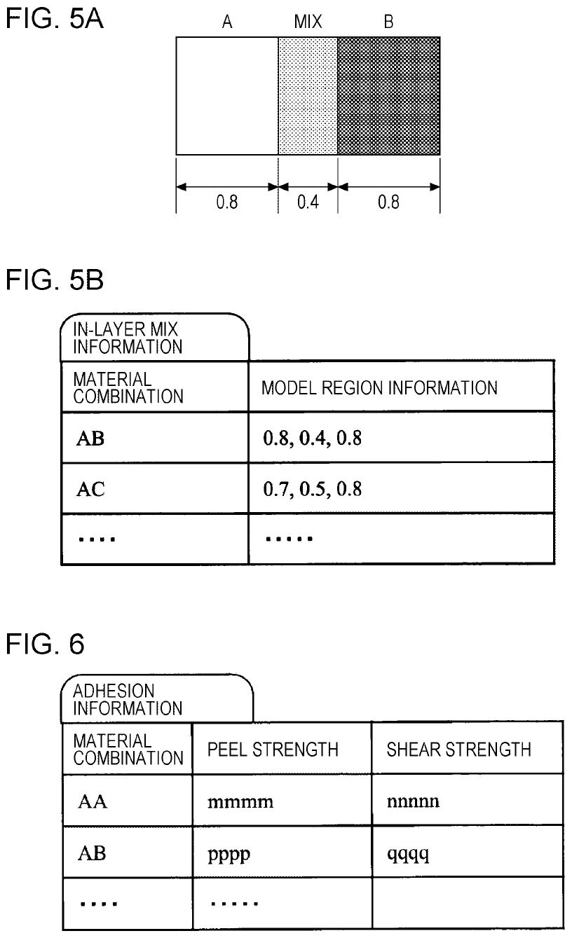

In the object data processing device 100, a basic data storage unit 102 stores basic data that acts as the material for computing the physical properties of the unit cell. The stored basic data includes data about the three elements described earlier (mixing of material in the same layer, adhesion between layers, and curing information according to depth). Examples of basic data for the three elements are illustrated in FIGS. 5A to 7B.

FIGS. 5A and 5B illustrate an example of information stipulating a structural analysis model of two adjacent voxels that accounts for the mixing of material between voxels (hereinafter called “in-layer mix information”). In this example, the letters A, B, C, and so on denote identifiers of materials, and two-letter strings such as AB and AC denote combinations of two materials. For example, AB denotes the combination of a voxel of a material A and a voxel of a material B adjacent to each other. Also, the region information is information indicating the widths of regions for each degree of mix between the materials in these two voxels Similarly to FIG. 2, the illustrated example assumes a model that divides the two voxels into three regions along the direction in which the voxels are arranged, namely a region of only one material, a region in which both materials are mixed uniformly, and a region of only the other material. In the region information, the widths of each of these regions are indicated as values relative to a voxel width of 1. From the region information, the divisions between regions along the advancement direction of formation in the same layer and the physical properties of the regions when generating a structural analysis model of unit voxels are determined. The physical properties of a region is determined according to the material included in the region. Note that in the example of FIGS. 5A and 5B, two voxels are divided into three regions, but may also be divided into more regions.

FIG. 6 illustrates an example of adhesion information between layers and between rows in the same layer. In the adhesion information, for each combination of two materials (including combinations of the same material with itself), physical properties such as the peel strength and the shear strength between voxels corresponding to the combination are indicated.

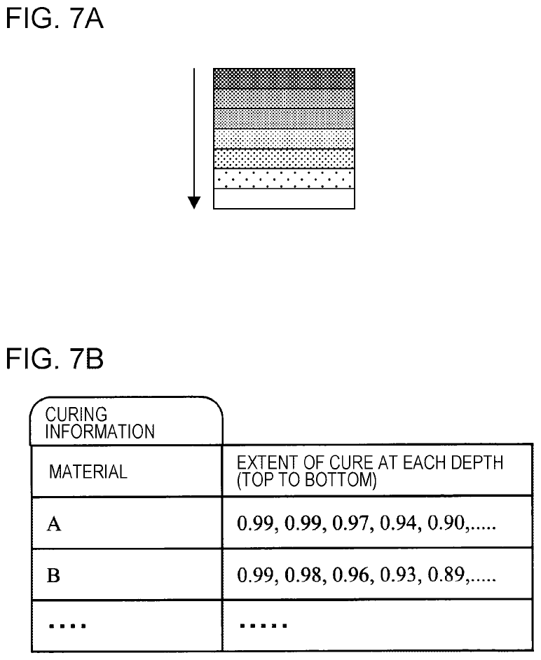

FIGS. 7A and 7B illustrate an example of curing information according to in-layer depth. In the curing information, for each material, a list of values of the extent of cure at each depth range from the surface from the curing energy source of the voxel is indicated.

In the basic data storage unit 102, information found by experiment or the like for various combinations of materials used by various forming devices 200 is stored. Note that since the information about the three elements described above may also vary depending on the size of the voxels, in such cases, information about these three elements may be found by experiment or the like for each of several different size ranges, and registered in the basic data storage unit 102.

The description will now return to FIG. 4. A forming device information input unit 104 receives the input of information about the forming device 200 to act as the target of resolution conversion. The input information includes the resolution of the forming device 200 and information indicating multiple materials used in formation by the forming device 200 (for example, a list of material names).

From the information about the materials used by the forming device 200 input from the forming device information input unit 104 and the basic data stored in the basic data storage unit 102, the cell information calculation unit 106 calculates information such as the physical properties of unit cells formable with the materials used by the forming device 200 and higher-order cells configurable from these units cells. In other words, for each of the unit cells formable from these materials, a structural analysis model of the unit cell is constructed using the information about the three elements described above, and by analysis using the model, the physical properties of these individual unit cells (that is, level 1 cells) are computed. Note that in the case in which the basic data storage unit 102 holds the information about the three elements described above for multiple size ranges of voxels, the cell information calculation unit 106 calculates the physical properties of unit cells using the information about the three elements in a size range corresponding to the resolution of the forming device 200.

Also, on the basis of the information about the unit cells computed in this way, the cell information calculation unit 106 calculates the physical properties of all level 2 cells configurable by combining these units cells as described above. Also, from the information about the level 2 cells, the physical properties of all configurable level 3 cells are calculated. With this arrangement, the physical properties of higher-order cells are calculated for the levels which have a possibility of being used. The calculated information about the unit cells and higher-order cells is saved in a cell information database (DB) 108.

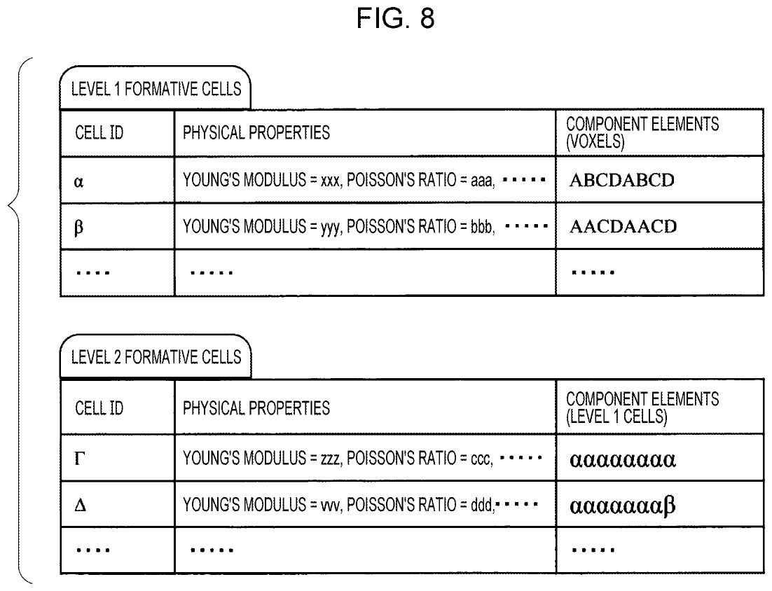

FIG. 8 illustrates an example of cell information stored in the cell information DB 108. In the illustrated example, for each level, the physical properties of cells and a list of component elements included in the cells are stored in association with an ID (that is, identification information) for each cell belonging to that level. The physical properties of a cell include values for one or more items such as Young's modulus, Poisson's ratio, and the strength. The list of component elements is a list of the IDs of cells one level below included in the current cell, arranged in a predetermined order. For example, as illustrated by example in FIG. 1, in the case in which a cell of a certain level (in the example of FIG. 1, unit cell=level 1 cell) contains eight lower cells (in the example of FIG. 1, voxel=level 0 cell) in a 2×2×2 arrangement, a predetermined order is set for the eight lower cells, and the IDs of these lower cells arranged in that order is the list of component elements described above. Note that the ID of a level 0 cell (that is, a voxel) is an ID that identifies the material. In other words, in the case of a forming device 200 that uses four materials, there are four types of level 0 cells, and IDs that identify these four types are used as the IDs of the level 0 cells. For example, the list of component elements of the unit cell with the cell ID=a is the string “ABCDABCD”, in which formative voxels whose materials are A, B, C, and D, respectively, are arranged in a predetermined order set with respect to the eight voxels forming the unit cell.

In FIG. 8, the term “formative cells”, such as “level 1 formative cells”, is used, but this indicates cells configured from the voxels in the resolution of the forming device 200 (that is, the unit cells and higher-order cells of each level). Even for the object data to be subjected to resolution conversion, since the unit cells and higher-order cells are also configured on the basis of voxels (these voxels not being limited to being the same size as the voxels of the forming device 200), to distinguish between these types of voxels, cells based on the voxels of the forming device 200 will be designated “formative cells”. Meanwhile, cells based on the voxels of the object data will be designated “data cells”.

In the foregoing, the cell information calculation unit 106 uses information inside the basic data storage unit 102 to compute information about the formative cells of each level dynamically from information about the forming device 200 that acts as the target, but this is merely one example. Instead, information about the formative cells may be computed in advance for each model of the forming device 200, and this information may be registered in the cell information DB 108 in association with a model ID.

Returning to the description of FIG. 4, the object data input unit 110 receives the input of object data to be subjected to resolution conversion. The object data is input into the object data input unit 110 over a network, or in a state of being recorded onto a portable recording medium.

The cell replacement unit 112 replaces the voxels of the object data or unit cells or higher-order cells containing these voxels (in other words, data cells) with formative cells. With this arrangement, the object data becomes a representation of an object as a collection of formative cells.

The resolution conversion unit 114 converts the individual formative cells included in the object data into a collection of voxels of the forming device 200. With this arrangement, the object data becomes data in the resolution of the forming device 200. The result of the conversion by the resolution conversion unit 114 is input into the forming device 200.

The above describes one example of the configuration of the object data processing device 100. Next, an example of the processes performed by this device will be described.

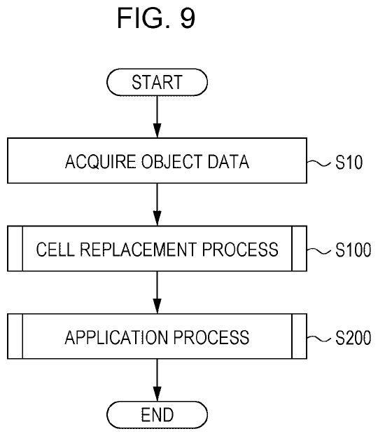

FIG. 9 illustrates an example of an overall processing procedure performed by the object data processing device 100. In this procedure, first, the object data processing device 100 acquires object data to process (S10). Next, the cell replacement unit 112 replaces each part of the object data expressed as a collection of voxels with unit cells or higher-order cells (S100). Additionally, an application process is executed on the data of the replacement result (S200). The resolution conversion process performed by the resolution conversion unit 114 is one example of the application process (S200).

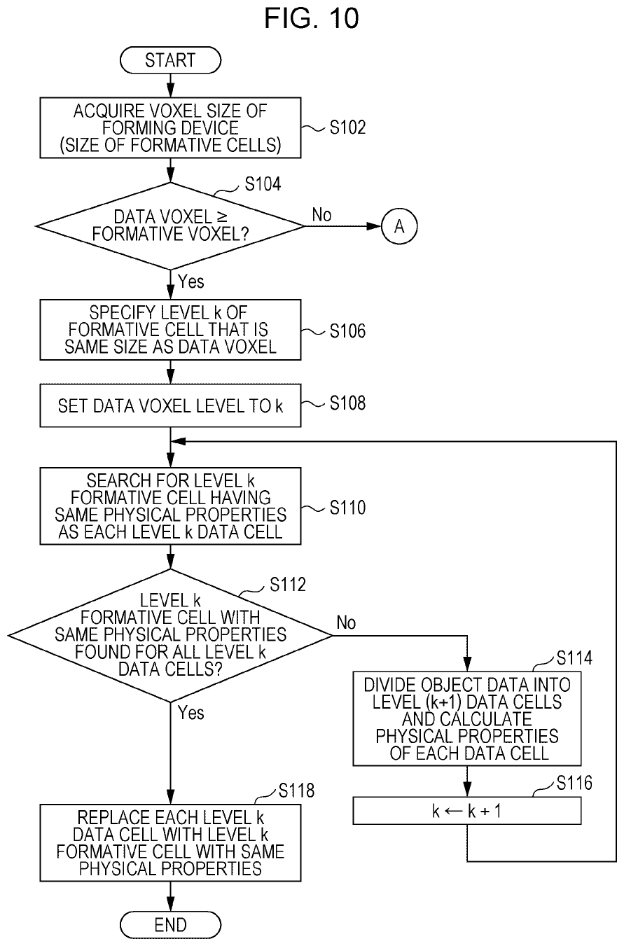

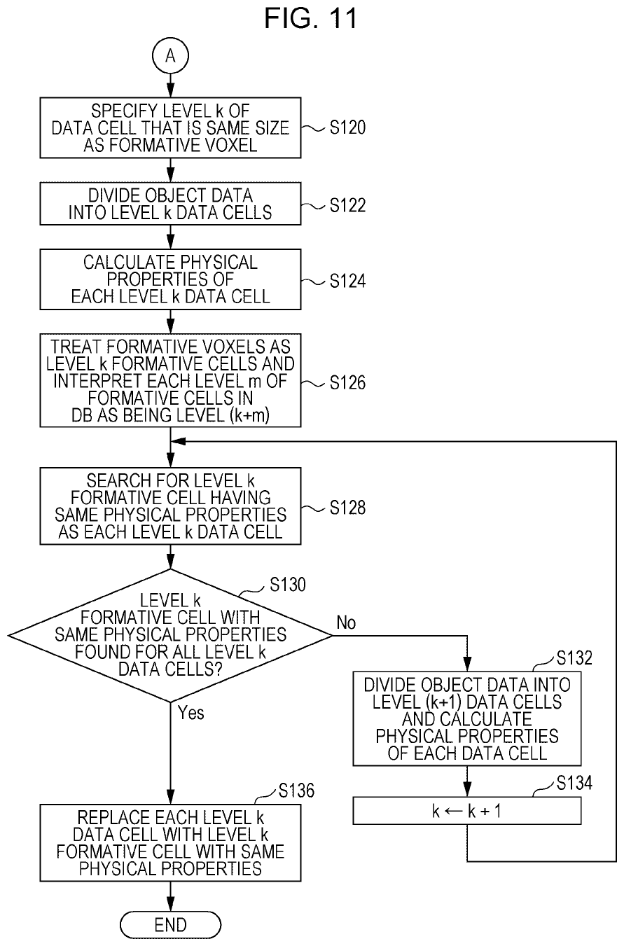

Next, FIGS. 10 and 11 will be referenced to describe an example of the procedure of the cell replacement process (S100) for resolution conversion as one example of the application process (S200). This procedure is executed in the case in which an instruction is given to execute a process (for example, outputting to the forming device 200) that demands resolution conversion of the input object data. The object data includes information about the resolution of the data. From the resolution information, the size of the voxels in the object data (hereinafter called the “data voxels”) is ascertained. For the cells of each level (that is, the unit cells and also the higher-order cells of level 2, 3, 4, and so on), since the cell configuration rules are predetermined, such as configuring a cell as a 2×2×2 arrangement of the cells one level below, the sizes of the cells of each level may also be calculated.

In this procedure, the cell replacement unit 112 first acquires information about the size of the formative voxels of the forming device 200 from the forming device information input unit 104 (S102). Subsequently, sizes of the data voxels and the formative voxels are compared (S104). In the case in which the data voxels are at least as large as the formative voxels, the cell replacement unit 112 computes a level k (where k is an integer equal to or greater than 1) at which the formative cells become the same size as the data voxels from among the formative cells of each level configured from the formative voxels (S106). Also, to simplify the description at this point, the level of the data voxels which is originally level 0 is taken to be level k (S108).

Next, for each level k data cell (in the first process loop, the data voxels themselves) included in the object data, the cell replacement unit 112 searches the cell information DB 108 for a level k formative cell having the same physical properties as the level k data cell (S110). The cell replacement unit 112 divides the object data into individual pieces the size of the level k data cell, and performs the process in S110 for each level k data cell obtained thereby.

At this point, in the case in which a material name is set for each data voxel of the object data, it is sufficient to calculate the physical properties of the level k data cell by a method similar to the case of the unit cells and the higher-order cells of each level for the formative cells described above by the cell information calculation unit 106. In this case, if basic data about the three elements such as the in-layer mix information (see FIG. 5) is available for each size range of the voxels in the basic data storage unit 102, the basic data corresponding to the size of the data voxels is used to calculate the attributes of the data cells of each level. Also, in the case in which physical properties are set for the data voxels instead of material names, it is sufficient to use the physical properties of each voxel to calculate physical properties by a method similar to the case of the unit cells and the higher-order cells of each level for the formative cells described above.

In S110, in the case in which a level k formative cell having completely the same physical properties as the level k data cell does not exist, a search is performed to find a level k formative cell having the closest physical properties within an allowable range as a formative cell with substantially the same physical properties. For example, an allowable range is determined for individual physical properties such as strength, Young's modulus, and Poisson's ratio, level k formative cells having physical properties within the allowable ranges from the physical properties of the level k data cell for all of the physical properties are extracted, and the cell having physical properties closest to the physical properties of the level k data cell from among the extracted cells is specified. Note that in the case in which a level k formative cell having physical properties within the allowable range from the physical properties of the level k data cell is not found, the level k data cell may not be replaced with a formative cell.

Next, the cell replacement unit 112 determines whether or not level k formative cells having substantially the same physical properties have been found in S110 for all level k data cells included in the object data (S112). In the case in which the determination result is No, the object data is divided into individual pieces the size of the level (k+1) data cell (in other words, level (k+1) data cells are configured from adjacent level k data cell groups inside the object), and the physical properties of each level (k+1) data cell are calculated by the cell information calculation unit 106 (S114). Subsequently, the level number k is incremented by 1 (S116), and the flow returns to the process of S110.

In the case in which the determination result of S112 is Yes, the cell replacement unit 112 replaces each level k data cell with each level k formative cell found to have substantially the same physical properties (S118). In other words, the ID of the replacing level k formative cell is associated with each level k data cell included in the object data. The process of the cell replacement unit 112 then ends.

In the case in which the determination result of S104 is No, as illustrated in FIG. 11, the cell replacement unit 112 computes the level k of data cells having the same size as the formative voxels (S120). Next, the object data is divided into individual pieces the size of the level k data cell (S122), and the cell information calculation unit 106 calculates the physical properties of each of these level k data cells (S124). The cell replacement unit 112 treats the formative voxels as level k formative cells, and treats each level m of the formative cells in the cell information DB 108 as level (k+m) (S126).

Next, for each level k data cell included in the object data, the cell replacement unit 112 searches the cell information DB 108 for a level k formative cell having substantially the same physical properties as the level k data cell (S128). It is determined whether or not level k formative cells having substantially the same physical properties have been found in S128 for all level k data cells included in the object data (S130). In the case in which the determination result is No, the object data is divided into individual pieces the size of the level (k+1) data cell, and the physical properties of each level (k+1) data cell are calculated by the cell information calculation unit 106 (S132). Subsequently, the level number k is incremented by 1 (S134), and the flow returns to the process of S128.

In the case in which the determination result of S130 is Yes, the cell replacement unit 112 replaces each level k data cell with each level k formative cell found to have substantially the same physical properties (S136). The process of the cell replacement unit 112 then ends.

By the replacement in S136, each part of the object data originally containing data voxels is replaced with formative cells configured from formative voxels having substantially the same physical properties.

In S106 of FIG. 10, the level k of formative cells having the same size as the data voxels is computed, while in S120 of FIG. 11, the level k of data cells having the same size as the formative voxels is computed. However, for example, in the case in which the size of the data voxels, that is, the length on a side is 1.5 times that of the formative voxels, the length of the size of the level 1 formative cells becomes 2 times the formative voxels, which is a non-negligible difference from the size of the data voxels. In this way, depending on the size relationship between the data voxels and the formative voxels, executing the processes in S106 and S120 may be difficult in some cases. In consideration of such cases, S106 and S120 may be refined as follows.

Namely, in this example, the size of the least common multiple of the side lengths of the data voxels and the formative voxels is computed. Subsequently, for each of the data voxels and the formative voxels, unit cells having the size of the least common multiple are configured. For example, in the case in which the ratio of the side lengths of the data voxels and the formative voxels is 3:2, a length of 6 relative to a side length of 1 for the formative voxels is computed as the least common multiple. In this case, for the data voxels, unit cells are configured as a 2×2×2 arrangement of voxels, while for the formative voxels, unit cells are configured as a 3×3×3 arrangement of voxels. Note that for higher-order cells, both the data cells and the formative cells are configured according to the same rule, such as configuring the level (k+1) cells as a 2×2×2 arrangement of level k cells for example. In this way, instead of S106 and S120, it is sufficient to perform a process of causing the sizes of the unit cells for the data voxels and the formative voxels to agree with each other. In this case, the cell information calculation unit 106 calculates the physical properties for each of the data and formative unit cells, and also calculates the physical properties for higher-order cells. Note that basic data (particularly in-layer mix information (FIG. 5)) is prepared in the basic data storage unit 102 for several sizes, such as for unit cells with a side length of 2, 3, and 5 voxels.

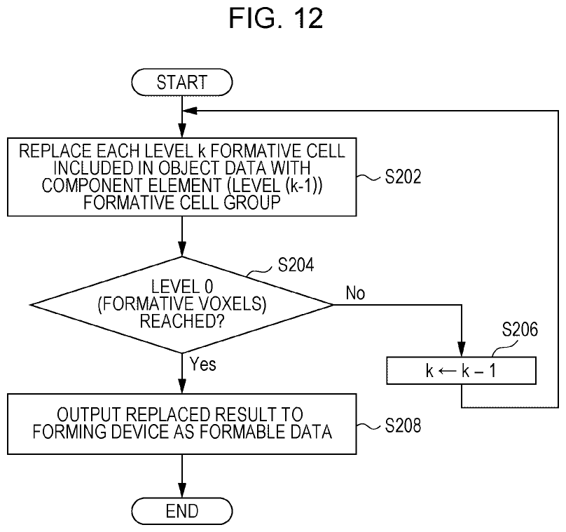

Next, as one example of the application process (that is, S200 of FIG. 9) performed by the object data processing device 100, an example of the resolution conversion process by the resolution conversion unit 114 will be described with reference to FIG. 12.

In the procedure of FIG. 12, the resolution conversion unit 114 receives object data input from the cell replacement unit 112. The object data is data representing an object as a collection of level k formative cells. The resolution conversion unit 114 decomposes each level k formative cell included in the object data into level (k−1) formative cells one level below. In this decomposition process, information about the level k formative cells in the cell information DB 108 is read out. Subsequently, the level k formative cells are replaced by each of the level (k−1) cells illustrated in the list of “component elements” included in the information (see FIG. 8), arranged in a predetermined order.

Next, the resolution conversion unit 114 determines whether or not the decomposition of S202 has reached level 0, or in other words the level of the formative voxels (S204), and if level 0 has not been reached, k is decreased by 1 (S206), and the flow returns to the process of S202. In the case in which the determination result of S204 is Yes, the object data decomposed (replaced with lower-order cells) by S202 has become a representation of an object as a collection of formative voxels. In other words, the object data is a representation of an object in the resolution of the forming device 200, which is called “formable data”. The resolution conversion unit 114 outputs the formable data to the forming device 200 (S208). The forming device 200 forms the object in accordance with the formable data.

<Increasing the Variety of Physical Properties>

In the case in which the forming device 200 forms an object using m types of materials (where m is an integer equal to or greater than 2) with different physical properties for example, when considered simply, only m varieties of physical properties may be realized. At this point, in the case in which object data containing voxel groups having n varieties of physical properties which are more than m is input, according to the simple thinking described above, the object may not be formable. In this example, there is proposed a data conversion technique for making it possible to accurately form an object expressed by object data, even in the case in which the varieties of physical properties of each part of the object data is greater than the varieties of physical properties of the group of materials used by the forming device 200.

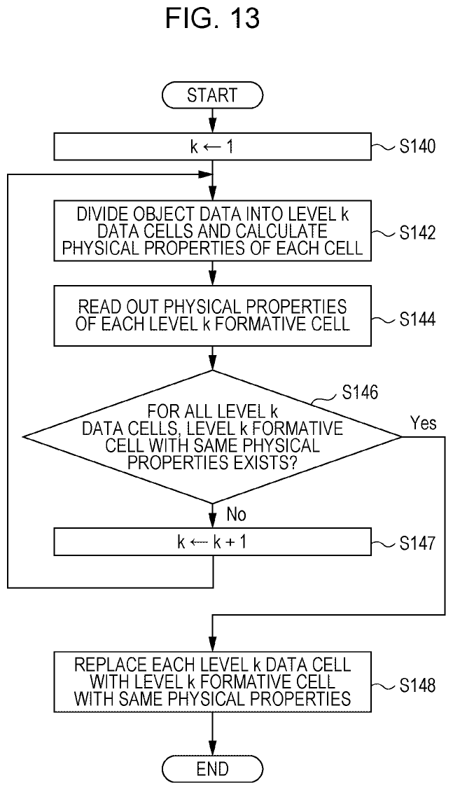

The device configuration of the object data processing device 100 for this example may be similar to that illustrated in FIG. 4. In this example, the cell replacement unit 112 executes the process illustrated by example in FIG. 13.

Namely, the cell replacement unit 112 first initializes a control variable k to 1 (S140). Next, the cell replacement unit 112 divides the object data into individual level k data cells (S142), and causes the cell information calculation unit 106 to calculate the physical properties of each level k data cell of the division result. It is sufficient to perform this calculation by a method similar to the method of calculating the physical properties in S114 of FIG. 10.

Next, the cell replacement unit 112 reads out the physical properties of each level k formative cell from the cell information DB 108 (S144). At this point, a level k formative cell is a formative cell of the same size as a level k data cell. In the case in which the formative voxels and the data voxels are different sizes, a level of formative cells stored in the cell information DB 108 is substituted such that formative cells of the same size as the level k data cells are treated as level k.

Subsequently, for all level k data cells included in the object data, the cell replacement unit 112 determines whether or not a level k formative cell having substantially the same physical properties as the physical properties of the data cell exists (S146). In the case in which the determination result is No, the physical properties of each part of the object data may not be expressed successfully with combinations of the materials of the forming device 200 at the granularity of level k. Accordingly, the cell replacement unit 112 raises the level by 1 (that is, increments k by 1) (S147), and performs the processes of S142 to S146 again. Since raising the level causes the size of the formative cells to become larger, the combinations of materials forming the formative cells increase. With this arrangement, since the variations of the physical properties of the formative cells increase, the probability of finding a formative cell having physical properties that are substantially the same as the physical properties of each part of the object data rises.

In the case in which the process loop of S142 to S147 is repeated in this way and the determination of S146 becomes Yes, the cell replacement unit 112 replaces each level k data cell of the object data with a level k formative cell having substantially the same physical properties (S148). With this arrangement, object data representing an object as a collection of level k formative cells is obtained. This object data is input into the resolution conversion unit 114.

The resolution conversion unit 114 converts this object data into formable data in units of formative voxels according to the process of FIG. 12. With this arrangement, formable data that approximately represents the physical properties of each part of the original object data with combinations of formative voxels containing the materials used by the forming device 200 is completed. The completed formable data is supplied to the forming device 200.

<Structural Analysis of Object>

Next, to reduce the load of the structural analysis of object data, an example of replacing voxel groups included in the object data with unit cells or higher-order cells will be described.

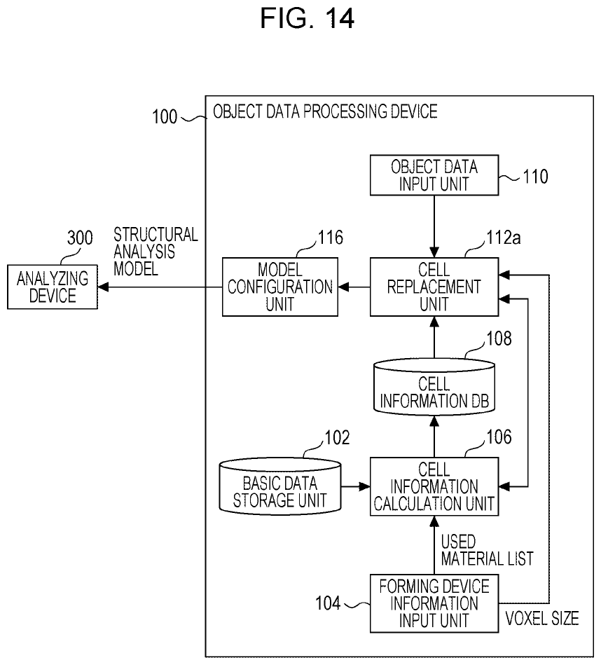

FIG. 14 illustrates an example of a functional configuration of the object data processing device 100 according to this example. The object data processing device 100 includes a model construction unit 116 instead of the resolution conversion unit 114 in the example of FIG. 4. The model construction unit 116 constructs a model for structural analysis (for example, a model for analysis by the finite element method) from object data in units of level k cells generated by the cell replacement unit 112a.

The cell replacement unit 112a, by replacing voxel groups in object data input from the object data input unit 110 with unit cells or higher-order cells, greatly reduces the number of elements (that is, data cells) in the object data compared to the case of voxel units. If voxel units are used, the component elements in the object data become extremely numerous, the assignment of materials in units of component elements and the combinations of arrangements of these elements become massive, and the structural analysis model increases in scale. Accordingly, in this example, by constructing a structural analysis model after first converting the object data from units of voxels to larger-sized units of unit cells or higher-order cells, the scale of the structural analysis model is moderated.

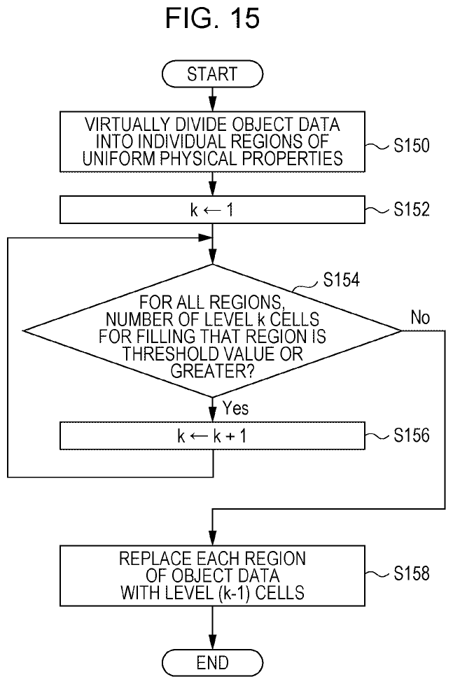

An example of a processing procedure executed by the cell replacement unit 112a is illustrated in FIG. 15.

In this process, the cell replacement unit 112a divides the object data to process into individual regions of uniform physical properties (S150). For example, in the case in which physical properties are set for each data voxel of the object data, the object data is divided into multiple regions having the same physical properties. In this case, the individual regions are collections of voxels having completely the same physical properties, for example. In addition, a criterion that the physical properties be completely the same may also not be not set in this way, and a collection of voxels whose physical properties are considered to be the same with a predetermined variation (for example, variance value) or less may also be treated as a single region. Also, in the case in which a material is set for each voxel of the object data, a contiguous part containing voxels of the same material may be treated as a single region, for example. Also, a range in which the same combination of multiple materials periodically repeats without being limited to the same material may also be treated as a single region. In this case, it is sufficient to treat repeating combination of materials as a single unit and compute the physical properties of the region by the same method as when computing the physical properties of unit cells. These regions are used in a determination of whether or not the level k cells satisfy the criteria of a microstructure described later.

Next, the cell replacement unit 112a initializes the control variable k to 1 (S152), and for each region of the object data, computes the number of level k data cells (in the first loop, equal to the unit cells) to fill the region, and determines whether or not the number is at least a threshold value (S154). This determination determines whether or not the level k data cells are of a size considered to be a microstructure for the individual regions (in other words, the cells are considered to be sufficiently small enough with respect to the region that it is safe to ignore the internal structure of the cells themselves). If a sufficiently large number of level k data cells may be repeatedly arranged inside a region, the cells are considered to be a microstructure for that region. If the level k data cells are considered to be a microstructure for all regions included in the object data, then converting the object data from a representation in units of voxels to a representation in units of level k data cells will not pose a large problem in terms of structural analysis. The number of level k data cells to fill a region that is subjected to the determination of S154 may be the total number of level k data cells arranged in the three-dimensional region. Additionally, the number may also be a representative value computed from the numbers of level k data cells that are arrangeable in each of the three directions of the length, width, and depth of the region. For the representative value, for example, representative values (such as average values, maximum values, or minimum values for example) of the number of arrangeable cells in each direction may be averaged for the three directions and used, or a representative value other than an average value, such as the maximum value among the representative values for each of the directions, may be used.

In the case in which the determination result of S154 is Yes, the cell replacement unit 112a increments k by 1 (S156), and makes the determination of S154 again. In other words, in this case, it is determined whether or not the data cells one level larger are considered to be a microstructure for the object.

By repeating the loop of S154 and S156, the highest level of data cells considered to be a microstructure for the object is specified. In other words, in the case in which the determination result of S154 becomes No, since the level k data cells at that point are not considered to be a microstructure for the object data, the previous level (k−1) is the highest level that is considered to be a microstructure. The cell replacement unit 112a converts the object data to data in units of level (k−1) data cells (S158). In other words, each region of the object data is replaced by level (k−1) data cells having physical properties that are substantially the same as that region. Since the level (k−1) data cells contain sufficiently numerous data voxels and have many variations of expressible physical properties, level (k−1) data cells able to express the physical properties of each region are normally found. However, as a precaution, the cell information calculation unit 106 may calculate the variations of physical properties expressible by the level (k−1) data cells, and check whether or not physical properties substantially the same as the physical properties of each region are included among the variations. Additionally, if there is a region having physical properties not expressible by the variations, the replacement process of S158 may be stopped, and the user may be notified.

The cell replacement unit 112a outputs the object data resulting from the replacement in S158 to the model configuration unit 116.

The model configuration unit 116 converts the object data received from the cell replacement unit 112a into a structural analysis model as one application process (that is, S200 of FIG. 9). In other words, the model configuration unit 116 uses publicly available techniques to construct a model for structural analysis of the object data, such as the finite element method, from the structure in units of the data cells of the received object data and the physical properties of each data cell. Since elements such as the mixing of materials between adjacent voxels, the adhesion between voxels such as between layers, and the distribution of the extent of cure in the depth direction are built into the calculations of the physical properties of the unit cells, the structural analysis model constructed at this point does not have to reflect these fine-grained elements.

Subsequently, the constructed structural analysis model is output to an analyzing device 300. The analyzing device 300 performs structural analysis calculations using the structural analysis model. The structural analysis model constructed from data cell groups has fewer structural elements than a structural analysis model constructed from the object data in units of voxels, and furthermore, fine-grained elements such as the mixing of materials between adjacent voxels do not have to be analyzed.

In the procedure of FIG. 15, level k cells configured in units of the voxels of the object data are used, but this is merely one example. In the case of anticipating a forming device that forms object data, level k cells configured on the basis of the voxel size of the forming device and a list of materials used in formation by the forming device may be used. In this case, the size of each level k cell is determined with reference to the size of the formative voxels. Also, in the case in which the level (k−1) cells used for replacement in S158 are determined, the variations of physical properties that the level (k−1) cells may take are computed on the basis of the list of materials. In other words, the physical properties of each unit cell are calculated from the materials information by the technique described above, and in order of decreasing level thereafter, the physical properties of each formative cell belonging to that level are calculated from the physical properties of the cells of component elements one level below.

Also, in the procedure of FIG. 15, all regions resulting from the division of the object are replaced by collections of cells of the same level, but this is merely one example. As a different example, for each individual region, the level, or in other words size, of cells to replace that region may be decided individually. In this case, it is sufficient the cell replacement unit 112a to specify, for each region, the level of cells of a size considered to be a microstructure given the size of the region, and to replace the region with repetitions of formative cells of that level. Also, at this time, the cell replacement unit 112a may also select the largest cells having physical properties that are substantially the same as the physical properties of the region from among the cells of sizes considered to be a microstructure given the size of the region, and replace the region with repetitions of the cells.

As yet another example, the size of the data cells for structural analysis may also be decided with reference to the size of a shape element included in the object. In other words, in some cases, the shape of an object includes small shape elements such as projections, and a minimum value of the size of such individual shape elements may be treated as an upper limit on the size of the data cells. With this arrangement, the shape of the object is expressed in units of data cells down to the smallest shape element of the object. In one example, the cell replacement unit 112a may replace each region of the object data with a collection of level k data cells of a size corresponding to the size of the minimum value. Also, in the procedure of FIG. 15, the upper limit of increasing the level k may be taken to be a level corresponding to the minimum value.

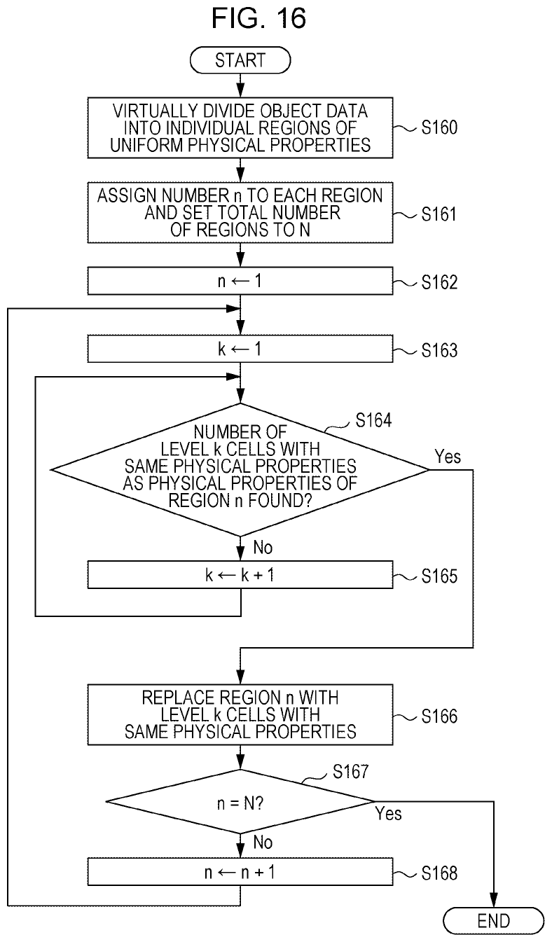

Also, as yet another example of a process by the cell replacement unit 112a, FIG. 16 illustrates a process of individually replacing each region considered to have uniform physical properties out of the object data with cells of the smallest size able to express those physical properties.

In this process, similarly to S150 in the procedure of FIG. 15, the cell replacement unit 112a divides the object data to process into individual regions of uniform physical properties (S160). Also, the cell replacement unit 112a assigns a sequential number n starting from 1 to each region obtained as a result of the division, and also sets the total number of these regions to N (S161).

Next, the cell replacement unit 112a initializes a control variable n denoting the region to 1 (S162). The subsequent processes from S163 to S168 are executed on the region assigned the number 1. In the following the region assigned the number n will be designated the region n.

In this process, the cell replacement unit 112a initializes a control variable k to 1 (S163), and for the region n of the object data, searches for a level k cell having physical properties considered to be the same as the physical properties of the region n (S164). The level k cells searched at this point may be level k formative cells or level k data cells. In the case of using level k formative cells as the level k cells at this point, in S164, it is sufficient to reference a database (that is, the cell information DB 108 of FIG. 4) similarly to the example illustrated in FIG. 8. Also, in the case of using level k data cells as the level k cells, for example, it is sufficient to prepare a database similar to the cell information DB 108 for the level k data cells, and reference the database. Also, in the search of S164, in the case in which the difference between the physical properties of the region n and the physical properties of the level k is a predetermined threshold value or less, it is determined that the physical properties of the two are considered to be the same.

In the case in which the determination result of S164 is Yes, the cell replacement unit 112a increments k by 1 (S165), treats the level k cells of the next larger level as the cells to process, and performs the determination of S164 again.

In the case in which the determination result of S164 becomes Yes as a result of repeating the loop of S164 and S165, the level k cells found at that point are cells of the smallest size having physical properties considered to be the same as the region n. The cell replacement unit 112a replaces the group of voxels inside the region with the level k cells found in S164 (S166).

Next, the cell replacement unit 112a determines whether or not the control variable n has reached the total number N of regions (S167). In the case in which the determination result is No, the cell replacement unit 112a increments n by 1 (S168), and repeats the process from S163.

In the case in which the determination result of S167 becomes Yes, the process of replacing voxel groups with cells has been completed for all regions n included in the object data. The cell replacement unit 112a outputs the object data resulting from the replacement to the model configuration unit 116. The model configuration unit 116 converts the object data received from the cell replacement unit 112a into a structural analysis model as one application process (that is, S200 of FIG. 9). In other words, the model configuration unit 116 uses publicly available techniques to construct a model for structural analysis of the object data, such as the finite element method, from the structure in units of the data cells of the received object data and the physical properties of each data cell.

<Design Support>

Next, an example of a device that provides design support using information about unit cells and higher-order cells will be described. With the device in this example, if a user designates the physical properties of each region of the object, the device automatically assigns materials to the individual voxels to achieve the physical properties.

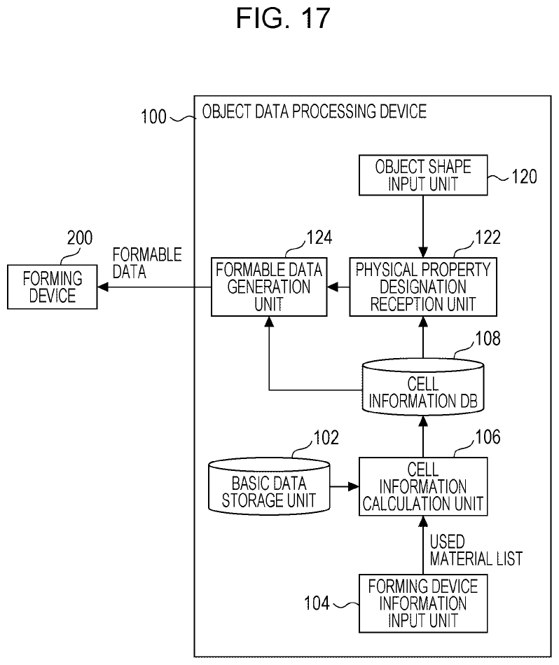

FIG. 17 illustrates an example of a functional configuration of the object data processing device 100 in this example. In the configuration of FIG. 17, the basic data storage unit 102 to the cell information DB 108 are similar to the elements denoted by the same signs in the device illustrated in FIG. 4. The cell information calculation unit 106 uses the data stored in the basic data storage unit 102 to calculate the physical properties of formative cells formable by the forming device 200, and registers the calculation results in the cell information DB 108.

An object shape input unit 120 receives the input of shape information about an object. The shape information is information indicating the shape of the object, and is generated by a computer-aided design (CAD) system for example. The shape information does not include information about the material and physical properties of each part of the object.

A physical property designation reception unit 122 receives the designation of physical properties from the user with respect to each region of the object indicated by the input object shape information. Also, the physical property designation reception unit 122 searches the cell information DB 108 for formative cells having physical properties that are substantially the same as the physical properties designated for a region, and by filling the region with repetitions of the formative cells, associates the IDs of the formative cells with that region of the object. A formable data generation unit 124 decomposes the formative cells of each region of the object into units of formative voxels according to a process similar to the process of resolution conversion illustrated in FIG. 12. By this process, formable data expressing the object as a collection of formative voxels with materials set thereto is generated from the object shape information. The forming device 200 forms the object in accordance with the formable data.

In the above configuration, the physical property designation reception unit 122 may also display a list of the physical properties of each level k formative cell registered in the cell information DB 108 on a user interface (UI) screen that receives the designation of the physical properties of each region of the object from the user. The user selects the physical properties to assign to each region from the list.

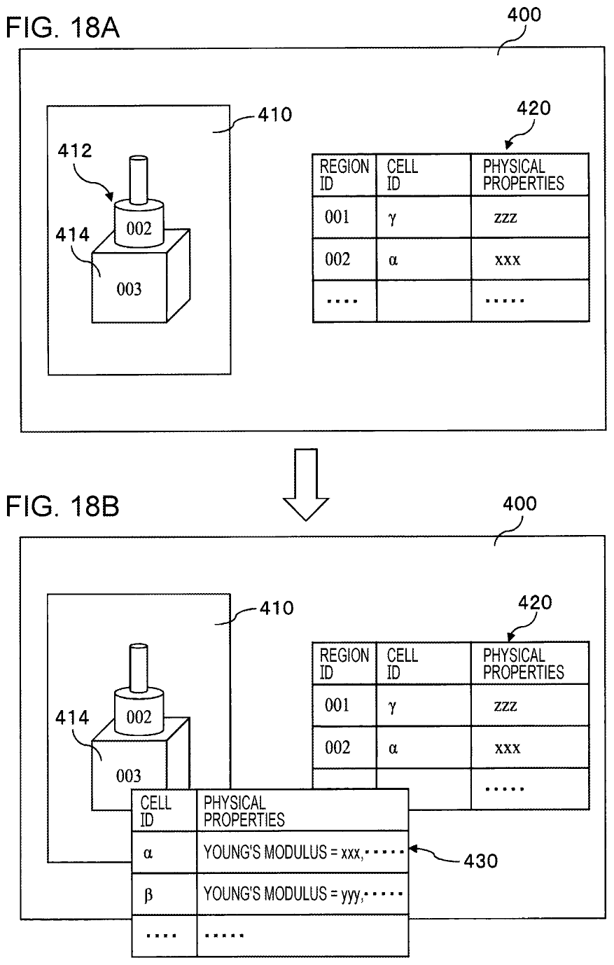

FIGS. 18A and 18B schematically illustrate an example of a UI screen 400 for designating physical properties in this way. On the UI screen 400, a shape display field 410 that displays the shape of an object and a designated content field 420 indicating the designated content of the physical properties for each region of the object are displayed. The shape displayed in the shape display field 410 is a 3D model for which the line-of-sight direction and the display size may be changed according to publicly available technology. In the illustrated example, an object 412 includes multiple three-dimensional sub-objects 414. Each individual sub-object is treated as a single region, and physical properties are designated. However, this is merely one example, and the user may also be able to specify how to divide the object 412 into regions in the shape display field 410. In the designated content field 420, in association with the ID of each region of the object, the ID of a formative cell designated for that region and the physical properties of the formative cell are displayed.

As illustrated in FIG. 18B, if the user selects a sub-object 414 (in the illustrated example, the sub-object with the ID “003”) of the object 412 in the shape display field 410 and performs an operation of calling a menu (for example, calling a context menu with a right click) for designating physical properties, a menu 430 is displayed on the screen. On the menu 430, the ID and the physical properties of each level k formative cell that is formable by the forming device are displayed. From the menu, the user selects the physical properties to assign to the sub-object, that is, to the region. The selection of physical properties is made by selecting a formative cell having the desired physical properties from the list of formative cells. The selection result is reflected in the designated content field 420.

At this point, the physical property designation reception unit 122 may limit the formative cell selection options listed on the menu 430 to only the formative cells of level k or below that are considered to be a microstructure given the size of the sub-object 414 selected by the user. Also, in this case, the selection options listed on the menu 430 may also be limited to only the formative cells corresponding to levels less than or equal to the size of a minimum shape such as a projection included in the sub-object 414.

Also, on the menu 430, the selection options may be displayed sorted in ascending or descending order of a physical property. In this case, for each region, the user chooses the selection option closest to the physical property the user wants to impart to the region from among the selection options sorted by the physical property. Additionally, the physical property designation reception unit 122 may also display a menu 430 illustrating selection options (that is, pairs of formative cells and physical properties) classified by each level k.

The above describes functions such as resolution conversion, a function of increasing variations of physical properties, structural analysis, and design support provided in an object data processing device, as well as device configurations and processing procedures for achieving such functions. Herein, the object data processing device is not required to include all of the functions described above. The object data processing device may have only one of the functions of resolution conversion, the function of increasing variations of physical properties, structural analysis, and design support described above, or may have two or more of the above functions.

The object data processing device illustrated by example above is realized by causing a computer to execute a program expressing each function described above, for illustrative purposes. Herein, the computer includes hardware having a circuit configuration in which a microprocessor such as a CPU, memory (first storage) such as random access memory (RAM) and read-only memory (ROM), a controller that controls a fixed storage device such as flash memory, a solid-state drive (SSD), or a hard disk drive (HDD), various input/output (I/O) interfaces, a network interface that controls connections to a network such as a local area network, and the like are interconnected via a bus or the like, for example. A program stating the processing content of each of these functions is saved to the fixed storage device such as flash memory via the network or the like, and installed in the computer. By having the CPU or other microprocessor load the program stored in the fixed storage device into RAM and execute the program, the function module group exemplified in the foregoing is realized.

The foregoing description of the exemplary embodiment of the present disclosure has been provided for the purposes of illustration and description. It is not intended to be exhaustive or to limit the disclosure to the precise forms disclosed. Obviously, many modifications and variations will be apparent to practitioners skilled in the art. The embodiment was chosen and described in order to best explain the principles of the disclosure and its practical applications, thereby enabling others skilled in the art to understand the disclosure for various embodiments and with the various modifications as are suited to the particular use contemplated. It is intended that the scope of the disclosure be defined by the following claims and their equivalents.

What is claimed:

1. An information processing device comprising:
a storage unit that stores, for each of a formative cell configured as a collection of multiple formative voxels that each are a minimum unit of formation by a forming device, specification information enabling a specification of which of multiple materials is used to form each formative voxel included in the formative cell, and physical properties of the formative cell;
a selection receiver that receives a selection of any formative cell stored in the storage unit as the material of each region included in an object; and
a formable data construction unit that replaces each region of the object with a collection of the formative cells received by the selection receiver for the region, and thereby constructs formable data expressing the object as a collection of the formative voxels each having a stipulated material.

2. The information processing device according to claim 1, wherein
the selection receiver presents a selection screen indicating the physical properties of each of the formative cells.

3. The information processing device according to claim 1, wherein
the selection receiver presents a selection screen indicating formative cells of a size equal to or less than a size considered to be a microstructure given the size of the region as selection options.

4. The information processing device according to claim 1, further comprising:
a calculation unit that, for each formative cell, calculates the physical properties of the formative cell using a structural analysis model reflecting a state of bonding between multiple formative voxels included in the formative cell and the material of each of the formative voxels, wherein
the storage unit stores, for each formative cell, the physical properties of the formative cell calculated by the calculation unit.

5. The information processing device according to claim 4, wherein
the calculation unit performs analysis using, as the structural analysis model, a model including mixed regions in which the materials of formative voxels adjacent to each other in a same voxel layer of the formative cells mix together.

6. The information processing device according to claim 4, wherein
the calculation unit performs analysis using, as the structural analysis model, a model in which boundary conditions indicating an adhesive state according to a combination of the materials of formative voxels adjacent to each other between voxel layers or between voxel rows in the formative cells are set.

7. The information processing device according to claim 4, wherein
the calculation unit performs analysis using, as the structural analysis model, a model reflecting, for each formative voxel in the formative cells, a distribution of an extent of cure according to a combination of the material of the formative voxel and a depth in a radiation direction of curing energy.

8. The information processing device according to claim 4, wherein
the calculation unit calculates the physical properties of the formative cells by performing a homogenization analysis using the structural analysis model of the formative cells.

9. The information processing device according to claim 2, wherein
the formative cells include level 1 formative cells configured from a first predetermined number of the formative voxels and level k formative cells configured from a kth (where k is an integer equal to or greater than 2) predetermined number of level (k−1) formative cells, and
the calculation unit calculates the physical properties of the level k formative cells by performing analysis using a structural analysis model reflecting a state of bonding between the kth predetermined number of level (k−1) formative cells included in the level k formative cells and the physical properties of each of the level (k−1) formative cells.

10. A non-transitory computer readable medium storing a program causing a computer to execute a process for processing information, the process comprising:
storing, for each of a formative cell configured as a collection of multiple formative voxels that each are a minimum unit of formation by a forming device, specification information enabling a specification of which of multiple materials is used to form each formative voxel included in the formative cell, and physical properties of the formative cell;
receiving a selection of any formative cell stored in the storage unit as the material of each region included in an object; and
replacing each region of the object with a collection of the formative cells received by the selection receiver for the region, and thereby constructing formable data expressing the object as a collection of the formative voxels each having a stipulated material.
